(19) United States
(12) Patent Application Publication
(10) Pub. No.: US 2020/0194159 A1
(43) Pub. Date: Jun. 18, 2020

(54) COIL DEVICE, COIL DEVICE WITH CIRCUIT BOARD, AND ELECTRICAL JUNCTION BOX

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-shi, Osaka (JP)

(72) Inventors: Toshiyuki Tsuchida, Yokkaichi, Mie (JP); Shigeki Yamane, Yokkaichi, Mie (JP)

(21) Appl. No.: 16/615,795

(22) PCT Filed: May 9, 2018
(86) PCT No.: PCT/JP2018/017880

§ 371 Date: Nov. 21, 2019

(30) Foreign Application Priority Data
May 23, 2017 (JP) 2017-101612
Sep. 21, 2017 (JP) 2017-181115

(51) Int. Cl. H01F 17/04; H01F 27/30; H05K 1/18; H05K 7/06; H05K 1/02

(52) U.S. Cl. CPC H01F 17/04; H01F 27/30; H01F 2017/048; H05K 7/06; H05K 1/0209; H05K 1/18

(57) ABSTRACT

A coil device includes a coil unit that includes a coil and a magnetic core, a case that is made of resin and that houses the coil unit, and a bus bar that includes a connection portion that can be connected to a conductive path of a circuit board, and that is held in close contact with the case. The case includes a mounting portion that can be mounted on a face of the circuit board.

### CROSS-REFERENCE TO RELATED APPLICATIONS

This application is the U.S. national stage of PCT/JP2018/017880 filed on May 9, 2018, which claims priority of Japanese Patent Application No. JP 2017-101612 filed on May 23, 2017 and Japanese Patent Application No. JP 2017-181115, filed on Sep. 21, 2017, the contents of which are incorporated herein.

### TECHNICAL FIELD

The present specification discloses a technique related to a coil device.

### BACKGROUND

Conventionally, a technique in which a bus bar is connected to a conductive path of a printed circuit board is known. In an electrical wire aid member disclosed in JP 5679959B, a plurality of lead portions are provided on the left side part of a main body portion that extends in a longitudinal direction, and the lead portions are inserted and soldered to through holes in a printed circuit board. The lead portions include a tapered lead part, and when the lead part is inserted into the through hole, a corner portion of the lead part comes in contact with and catches the inner wall of the through hole, such that the electrical wire aid member mechanically stands on the printed circuit board. In addition, a plurality of protruding portions that are shorter than the lead portions are provided between the lead portions, and the protruding portions are held in contact with the printed circuit board.

Incidentally, since the above-described electrical wire aid member keeps a position with respect to the printed circuit board with the lead terminals and protruding portions, there is a concern in that, when the electrical wire aid member is subject to vibration, connection reliability between the electrical wire aid member and the printed circuit board will be deteriorated due to stress acting on a position where the electrical wire aid member is soldered to the through hole of the printed circuit board.

The technique disclosed in the present specification has been made in view of the above-described circumstances, and an object of the present disclosure is to suppress deterioration of the reliability of the connection between the conductive path of the circuit board and the bus bar.

### SUMMARY

A coil device disclosed in the present specification includes: a coil unit that includes a coil and a magnetic core; a case that is made of resin and that houses the coil unit, and a bus bar that includes a connection portion that can be connected to a conductive path of a circuit board, and that is held in close contact with the case, and the case includes a mounting portion that can be mounted on a face of the circuit board.

With the above-described configuration, the bus bar is held by the case, and the mounting portion of the case is mounted on the circuit board, and thus stress due to vibration of the vehicle or the like is less likely to be transferred to the connection portion of the bus bar. This makes it possible to suppress deterioration of the reliability of the connection between the conductive path of the circuit board and the bus bar.

Furthermore, since the bus bar is held in close contact (intimate contact) with the case, it is possible to transfer heat in the bus bar to the case, and dissipate heat from the case, and thus heat dissipation can be improved.

The following embodiments are preferable as embodiments of the technique described in the present specification.

The bus bar may include a plurality of the connection portions, and a main body portion that is shaped like a plate and that connects the connection portions to each other, the two faces of the main body portion being in close contact with the case.

In this manner, heat conductivity from the bus bar to the case can be improved.

The bus bar may be shaped like a plate, and the plate face of the bus bar may be held by the case in the orientation intersecting the face of the circuit board.

Since the plate face of the bus bar is held by the case in the orientation intersecting the face of the circuit board, the area occupied by the bus bar on the circuit board can be reduced. In this manner, the area on which electric components can be mounted on the circuit board can be enlarged.

The case may include a rectangular tubular portion that is shaped like a rectangular tube and that houses the coil unit, and a back wall portion that closes the rectangular tubular portion, the rectangular tubular portion may include a pair of opposing wall portions that oppose each other, and a connecting wall portion that connects the pair of opposing wall portions, and the bus bar may include a first plate portion that is held in close contact with the back wall portion, and a second plate portion that extends in a direction intersecting the first plate portion and that is held in close contact with the opposing wall portions.

In this manner, magnetic flux (electromagnetic noise) that leaks from the coil can be shielded by the bus bar. Furthermore, since the contact area between the bus bar and the case can be enlarged, heat dissipation of the bus bar can be improved.

A plurality of the bus bars may be provided, and the bus bars may be arranged so as to overlap one another with a gap therebetween.

In this manner, magnetic flux (electromagnetic noise) that leaks from the coil can be more reliably shielded by the plurality of bus bars.

A coil device with circuit board may include the circuit board on which the mounting portion is mounted, and the coil device, and the circuit board may include a through hole into which the connection portion is inserted and soldered.

In this manner, stress due to vibration of a vehicle and the like is less likely to be transferred to the portion at which the connection portion is soldered to the through hole, and thus, in a configuration where the soldered portion is likely to fail, deterioration of connection reliability between the connection portion and the circuit board can be suppressed.

An electric junction box may include the coil device with circuit board, and a heat dissipation member that is placed on the circuit board. The circuit board may be a printed circuit board, and the printed circuit board may be placed on the heat dissipation member.

In this manner, compared to a configuration where the bus bar that is made of metal plate material is placed between the printed circuit board and the heat dissipation member, it is possible to directly transfer heat in the printed circuit board to the heat dissipation member.

The electrical junction box may include a frame that is made of resin and that is mounted on the circuit board, and the case may be fixed to the frame.

In this manner, it is possible to fix the coil device to the frame and absorb, to the frame, the stress due to a vehicle vibration, whereas heat in the bus bar can be transferred from the case to the frame, and then dissipate the heat via the frame.

Advantageous Effects of Disclosure

According to the technique described in the present specification, it is possible to suppress deterioration in reliability of the connection between the conductive path of the circuit board and the bus bar.

### BRIEF DESCRIPTION OF DRAWINGS

FIG. 1 is a perspective view showing an electrical junction box according to a first embodiment in a state where a cover has been removed.

FIG. 2 is a plan view showing the electrical junction box in a state where a cover has been removed.

FIG. 3 is a cross-sectional view taken along line A-A in FIG. 2.

FIG. 4 is a side view showing a state where a coil device has been mounted on the circuit board.

FIG. 5 is a plan view showing the coil device.

FIG. 6 is a cross-sectional view taken along line B-B in FIG. 5.

FIG. 7 is a bottom view showing the coil device.

FIG. 8 is a perspective view showing a coil device according to a second embodiment.

FIG. 9 is a plan view showing the coil device.

FIG. 10 is a cross-sectional view taken along C-C in FIG. 9.

FIG. 11 is a perspective view showing an electrical junction box according to a third embodiment in a state where a cover has been removed.

FIG. 12 is a plan view showing the electrical junction box in a state where a cover has been removed.

FIG. 13 is a perspective view showing a coil device.

FIG. 14 is a front view showing the coil device.

FIG. 15 is a perspective view showing a bus bar.

FIG. 16 is a front view showing the bus bar.

FIG. 17 is a perspective view showing a coil device according to a fourth embodiment.

FIG. 18 is a perspective view showing a bus bar.

FIG. 19 is a perspective view showing a coil device according to a fifth embodiment.

FIG. 20 is a plan view showing a coil device.

FIG. 21 is a cross-sectional view taken along D-D in FIG. 20.

FIG. 22 is a front view showing the coil device.

FIG. 23 is a perspective view showing a second bus bar.

### DETAILED DESCRIPTION OF PREFERRED EMBODIMENTS

### First Embodiment

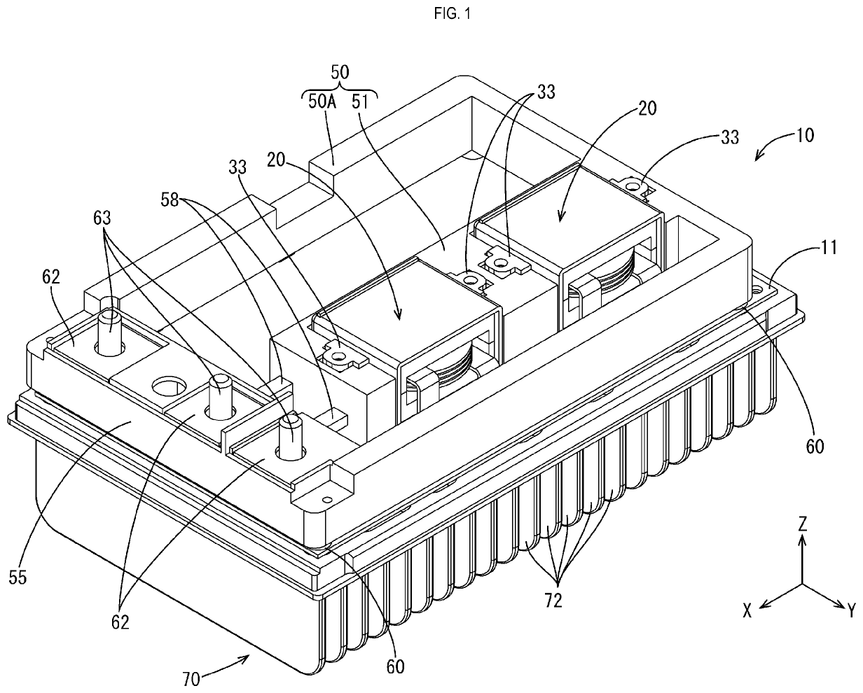

Hereinafter, a first embodiment will be described with reference to FIGS. 1 to 7.

An electrical junction box 10 is, for example, arranged in an electric power supply path between a power source such as a battery for a vehicle such as an electric car and a hybrid car, and loads constituted by in-vehicle electric components such as a lamp, and a motor and the like, and can be used in a DC-DC convertor, an inverter, and the like, for example. The following description will be given assuming the X direction shown in FIG. 1 as the left direction, the Y direction as the front direction, and the Z direction as the upper direction.

### Electrical Junction Box 10

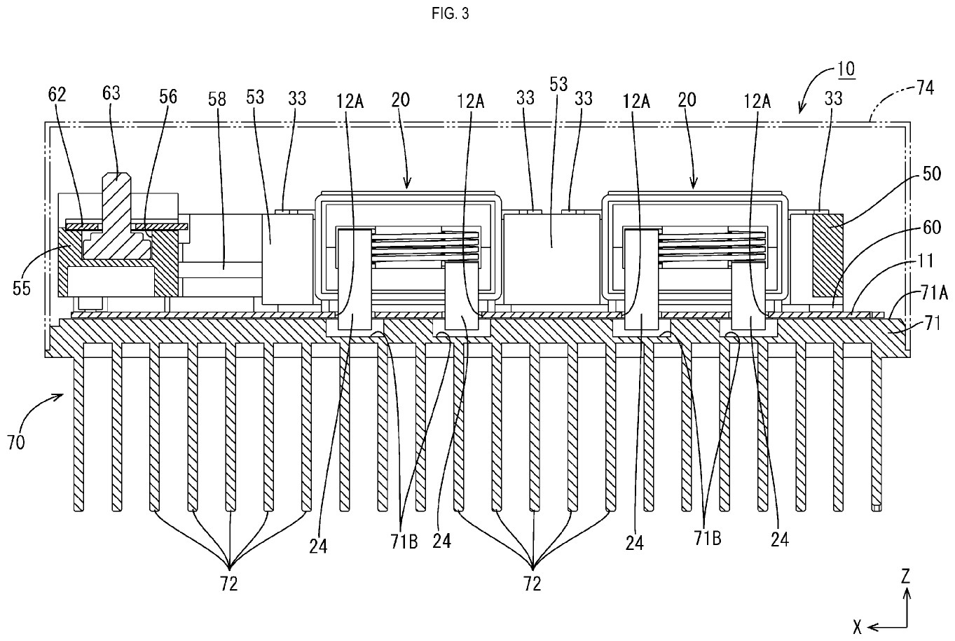

As shown in FIG. 3, the electrical junction box 10 includes: a circuit board 11, coil devices 20 that are mounted on the circuit board 11, a synthetic resin frame 50 that is arranged at a position different from the position of the coil devices 20 on the circuit board 11, and a heat dissipation member 70 that is placed on the lower side of the circuit board 11 and dissipates heat in the circuit board 11 to the outside.

### Circuit Board 11

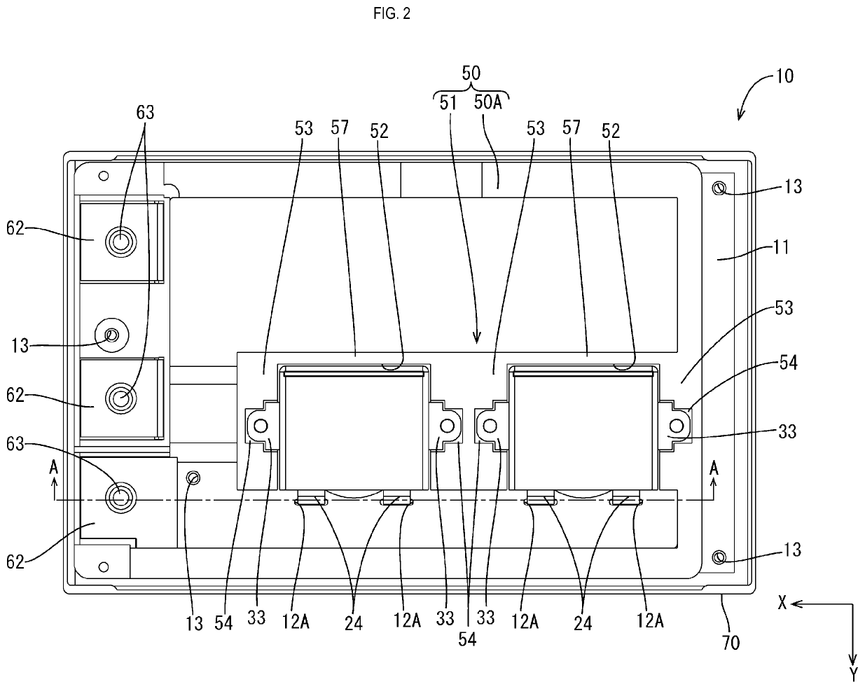

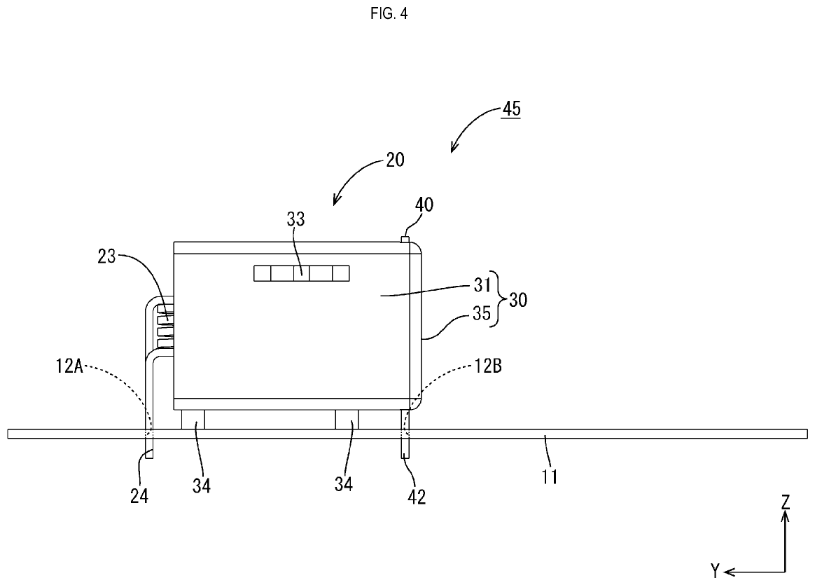

The circuit board 11 is a rectangular printed circuit board formed by an insulative plate on which a conductive path formed of a copper foil or the like is printed, and a plurality of through holes 12A and 12B penetrate the circuit board 11. As shown in FIG. 4, an insertion portion 24 of a coil 22 and a connection portion 42 of a bus bar 40 are inserted into and soldered to the through holes 12A and 12B. The shape and size of the through holes 12A and 12B correspond to the shape and size of the cross-section of the insertion portion 24 and the connection portion 42 that are inserted into the through holes 12A and 12B. Furthermore, as shown in FIG. 2, a plurality of screw holes 13 penetrate through the circuit board 11 and the circuit board 11 is fixed to the heat dissipation member 70 with screws. The circuit board 11 is placed on the entire upper face of the heat dissipation member 70 excluding the edge portion, and a plurality of electric components are mounted on the circuit board 11. The electric components include the coil devices 20, a not-shown FET (Field Effect Transistor), a capacitor, a resistor, and the like.

### Coil Device 20

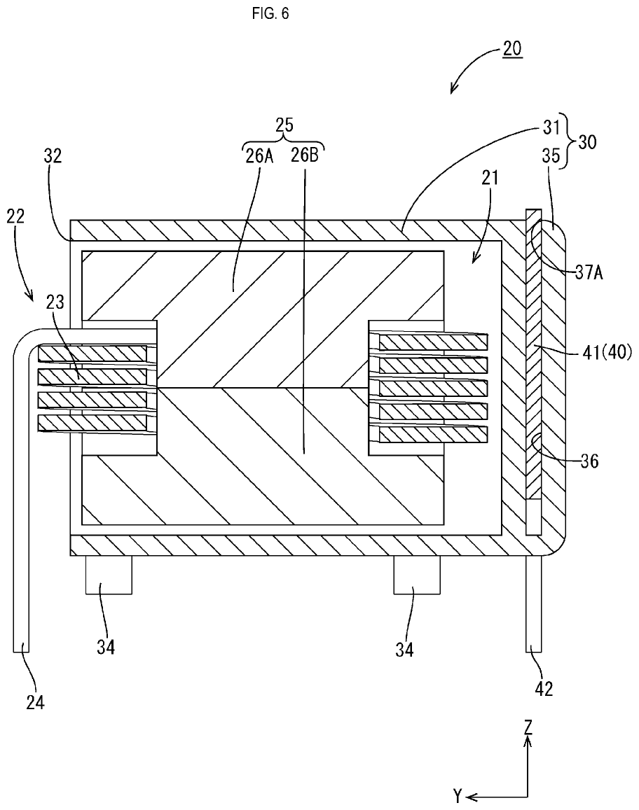

The coil devices 20 may be choke coils that smooth an output voltage, for example, and as shown in FIG. 6, each coil device 20 includes a coil unit 21, a case 30 that houses the coil unit 21, and the bus bar 40 that is held by the case 30.

### Coil Unit 21

The coil unit 21 includes a coil 22 and a magnetic core 25. The coil 22 is a so-called edgewise coil that is made of a material such as copper or a copper alloy and formed by winding a rectangular wire, and the outside of the coil 22 is coated with an enamel coating. The coil 22 is bent into an L-shape on the winding end side of the wound portion 23 that is wound a plurality of times with the direction perpendicular to the face of the circuit board 11 as the axis. A pair of insertion portions 24 that are connected to the conductive path of the circuit board 11 extend downward. The pair of insertion portions 24 are linear and arranged in parallel with each other.

The magnetic core 25 is formed of a magnetic material having a high magnetic permeability such as ferrite, is constituted by combining a pair of divided members 26A and 26B, and includes: a columnar portion that is columnar-shaped and inserted into the inside of the wound portion 23, an outer wall arranged outside of the wound portion 23, and a connecting wall that connects the columnar portion and the outer wall with each other, and all of these are formed in one piece.

### Case 30

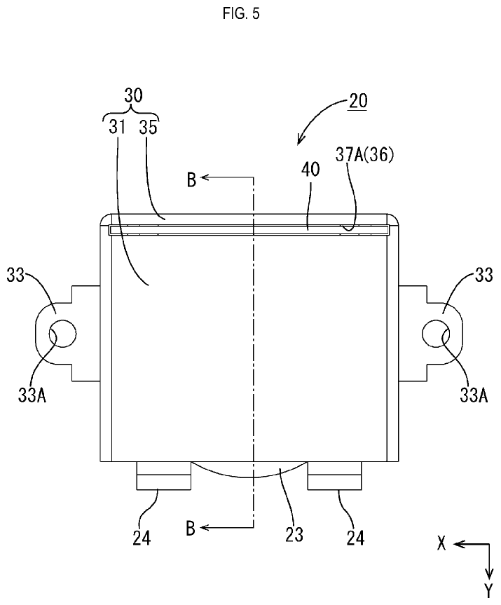

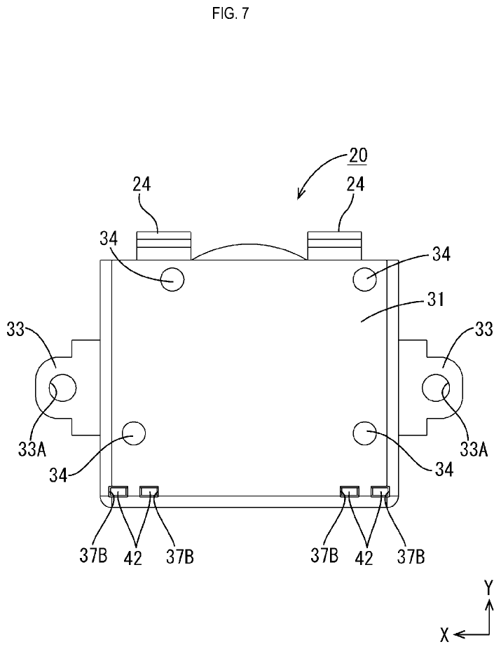

The case 30 is formed of an insulative synthetic resin, and an engineering plastic (heat resistance: at least 100° C., strength: at least 50 MPa, bending elastic modulus: at least 2.4 GPa) can be used for example. A resin having a high heat-dissipation property is preferably used. The case 30 is provided with a rectangular tubular portion 31 that is shaped like a rectangular tube and a back wall portion 35 that closes the rectangular tubular portion 31. A rectangular opening portion 32 into which the coil unit 21 can be inserted is formed at the front end portion of the rectangular tubular portion 31. As shown in FIGS. 5 and 7, screwed portions 33 shaped like a plate protrude from the left and right sides of the rectangular tubular portion 31. An insertion hole 33A for insertion of a shaft portion of a screw penetrates each of the screwed portions 33 such that the screwed portion 33 is screwed to a screwing portion 54 of the frame 50. Four mounting portions 34 that are placed on the upper face of the circuit board 11 are formed on a bottom (lower) face of the rectangular tubular portion 31. The mounting portions 34 have a columnar shape, and a pair of mounting portions 34 arranged on the left and right end sides on the rear side of the bottom face of the rectangular tubular portion 31 are arranged at positions near a screwed portion 33 and a connection portion 42.

As shown in FIG. 6, a press-fit hole 36 into which the bus bar 40 is press-fitted is formed in the back wall portion 35. The upper end portion of the press-fit hole 36 is an inlet 37A into which the bus bar 40 can be inserted, and as shown in FIG. 7, the lower end portion of the press-fit hole 36 is an outlet 37B from which the connection portion 42 of the bus bar 40 can be led out. When the bus bar 40 is press-fitted into the press-fit hole 36, the front and back plate faces of a main body portion 41 of the bus bar 40 come in close contact with the entirety of the opposing inner walls of the press-fit hole 36. In the present embodiment, the back wall portion 35 is formed so that the portion in front of the press-fit hole 36 and the portion behind the press-fit hole 36 are both thicker than the rectangular tubular portion 31 (and the main body portion 41 of the bus bar 40). Although a gap is formed between the coil unit 21 (the coil 22 and the magnetic core 25) and the inner face of the case 30, the configuration is not limited to this, and the coil unit 21 (the coil 22 and the magnetic core 25) and the inner face of the case 30 may also be in contact with each other.

### Bus Bar 40

The bus bar 40 is shaped like a plate, and for example, made of metal such as copper, a copper alloy, aluminum, or an aluminum alloy, and formed by punching a metal plate material. A relatively large current (driving current of a vehicle, etc.) flows through the bus bar 40 compared to the current flowing through the conductive path of the circuit board 11. The bus bar 40 has a constant width and extends in the left-right direction along the back wall portion 35, and includes the main body portion 41 that is embedded in the back wall portion 35 of the case 30, and a plurality (in the present embodiment, four) of the connection portions 42 that are narrower than the main body portion 41 and extend downwards, and that are exposed from the lower end portion of the back wall portion 35 to the outside. The main body portion 41 is embedded in the entire area of the back wall portion 35.

The connection portions 42 are electrically connected to the conductive path of the circuit board 11 by passing through the through holes 12B of the circuit board 11 and being soldered to the through holes 12B. As shown in FIG. 4, the above-described coil device 20 forms a coil device 45 with circuit board by being mounted on the circuit board 11.

### Frame 50

The frame 50 is made of an insulative synthetic resin, and as shown in FIG. 1, includes a rectangular frame body portion 50A that is arranged along the edge portion of the upper face of the heat dissipation member 70, and a coil holding portion 51 that extends so as to connect the inner sides of the frame body portion 50A and that holds the pair of coil devices 20.

The frame body portion 50A includes a receptacle 55 on which a plurality of terminal portions 62 that can be connected to the external terminals are mounted. The receptacle 55 is arranged between the terminal portions 62 and the circuit board 11, and keeps the position of the terminal portions 62, and has a recessed portion 56 that houses a head portion of stud bolts 63 as shown in FIG. 3. The terminal portions 62 are arranged side by side, and penetrated by bolt holes. The shaft portions of the stud bolts 63 are inserted into the bolt holes. The terminal portions 62 are, for example, electrically connected to the conductive path of the circuit board 11.

The receptacle 55 and the coil holding portion 51 are linked with each other at a linking portion 58. A plurality of holding portions 60 that are mounted on the circuit board 11 and hold the frame 50 are formed at the four corners of the lower (back) face of the frame body portion 50A. The frame 50 and the circuit board 11 may also be fixed to each other by inserting a screw into the screw hole of the circuit board 11 from below and screwing the circuit board 11 to the lower (back) faces of the holding portions 60, for example.

As shown in FIG. 2, a pair of housing recessed portions 52 into which the pair of coil devices 20 can be fitted are formed in the coil holding portion 51. The housing recessed portions 52 each have side wall portions 53 arranged on the two sides of the coil device 20, and a rear wall portion 57 that is arranged to the rear of the coil device 20 and that links the left and right side wall portions 53. A screwing portion 54 that has a screw hole through which the screwed portion 33 of the case 30 can be screwed is provided on the upper face of the side wall portions 53. When the coil device 20 is fitted into the housing recessed portion 52, the wall faces of the side wall portion 53 and the back wall portion 57 are arranged so as to oppose the outer face of the case 30 with a slight gap therebetween so that heat can be conducted therebetween.

### Heat Dissipation Member 70

A heat dissipation member 70 is formed of a highly heat-conductive metallic material such as aluminum, an aluminum alloy, copper, a copper alloy, or the like, and as shown in FIG. 3, includes a plate-shaped plate portion 71 on which the circuit board 11 is mounted, and a plurality of heat dissipation fins 72 that are provided side by side below the plate portion 71. A flat face 71A, a releasing recessed portion 71B for preventing the plate portion 71 from coming in contact with the insertion portion 24 of the coil 22 and the connection portions 42 of the bus bar 40, and screw holes (not shown) that can be used to fix the plate portion 71 to the circuit board 11 by screws are formed on the upper face of the plate portion 71. A cover 74 covers the space above the frame 50 and the coil devices 20. The cover 74 is formed of a synthetic resin or metal and shaped like a box that is open downward. The cover 74 is fixed to the frame 50 by a screw, for example.

Next, assembling of the electrical junction box 10 will be described.

The coil device 20 is formed by fitting the coil unit 21 into the case 30 and fitting the bus bar 40 into the press-fit hole 36 in the case 30 (FIG. 6). Note, that it is also possible to fix the bus bar 40 into the press-fit hole 36 by applying an adhesive agent after press-fitting the bus bar 40. Then, the screwed portions 33 of the case 30 are fixed to the screwing portion 54 of the frame 50 with screws.

Next, the circuit board 11 is attached to the coil device 20 from below, the insertion portions 24 of the coil 22 and the connection portions 42 of the bus bar 40 are inserted into the through holes 12A and 12B of the circuit board 11, and are subjected to flow soldering. In this manner, the plurality of insertion portions 24 and the connection portions 42 that are inserted into the through holes 12A and 12B are soldered into the through holes 12A and 12B of the circuit board 11, and connected to the conductive path of the circuit board 11. Next, the heat dissipation member 70 is placed on the lower side of the circuit board 11, and the circuit board 11 is fixed to the heat dissipation member 70 with screws. At this time, an insulative layer made of an adhesive agent or the like may also be formed between the circuit board 11 and the heat dissipation member 70. Then, the cover 74 is placed from above to form the electrical junction box 10 (see FIG. 3).

The operations and effects of the present embodiment will be described next.

The coil device 20 includes: a coil unit 21 including a coil 22 and a magnetic core 25; a case 30 that is made of a resin and that houses the coil unit 21; and the bus bar 40 that has the connection portion 42 that can be connected to the conductive path of the circuit board 11, and that is press-fitted into the press-fit hole 36 of the case 30 (held in close contact with the case 30), and the case 30 includes the mounting portion 34 that is to be mounted on a face of the circuit board 11.

According to the above-described embodiment, the bus bar 40 is held by the case 30, and the mounting portion 34 of the case 30 is mounted on the circuit board 11, and thus stress due to vibrations of the vehicles or the like is not likely to act on the connection portion 42 of the bus bar 40. In this manner, it is possible to suppress deterioration in the reliability of the connection between the conductive path of the circuit board 11 and the bus bar 40.

Furthermore, since the bus bar 40 is held in close contact with the case 30 by being press-fitted into the press-fit hole 36 of the case 30, it is possible to transfer heat in the bus bar 40 to the case 30, dissipate heat from the case 30, and thus heat dissipation can be improved. Note, that the bus bar 40 being “in close contact with” the case 30 means that at least part of the outer face (plate face) of the bus bar 40 is in contact with the case 30, and cannot be separated from the case 30.

In addition, the bus bar 40 includes a plurality of connection portions 42 and the plate-shaped main body portion 41 that connects the connection portions 42 to each other, the two faces of the main body portion 41 being in close contact with the case 30. In this manner, heat conductivity from the bus bar 40 to the case 30 can be improved.

Furthermore, the bus bar 40 is shaped like a plate, and the plate face of the bus bar 40 is held by the case 30 in the direction perpendicular to (intersecting) the face of the circuit board 11.

In this manner, the area occupied by the bus bar 40 in the circuit board 11 can be reduced, and thus the area on which the electric components can be mounted in the circuit board 11 can be enlarged.

Furthermore, the electrical junction box 10 includes a coil device 45 with circuit board, and the heat dissipation member 70 that is placed on the circuit board 11. The circuit board 11 is the printed circuit board and the printed circuit board is placed on the heat dissipation member 70.

In this manner, compared to a structure in which a bus bar formed of a metallic plate material is placed between the circuit board 11 and the heat dissipation member 70, it is possible to directly transfer heat in the circuit board 11 to the heat dissipation member 70.

Furthermore, the synthetic-resin frame 50, that is mounted on the circuit board 11 and to which the case 30 is fixed, is provided.

In this manner, it is possible to fix the coil device 20 to the frame 50, absorb stress due to vibrations of the vehicle in the frame 50, and transfer heat in the bus bar 40 from the case 30 to the frame 50, and dissipate the heat via the frame 50.

### Second Embodiment

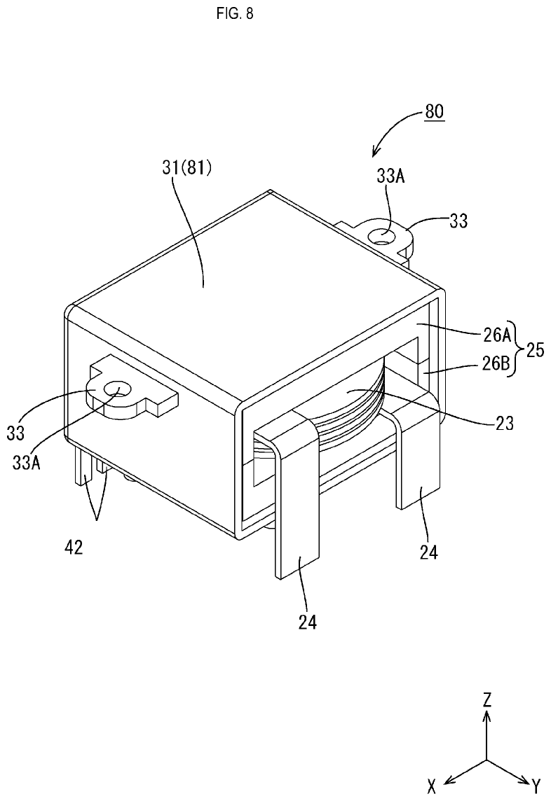

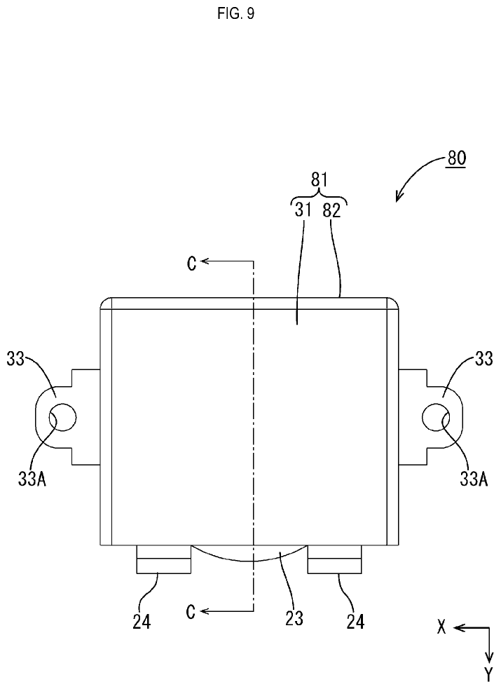

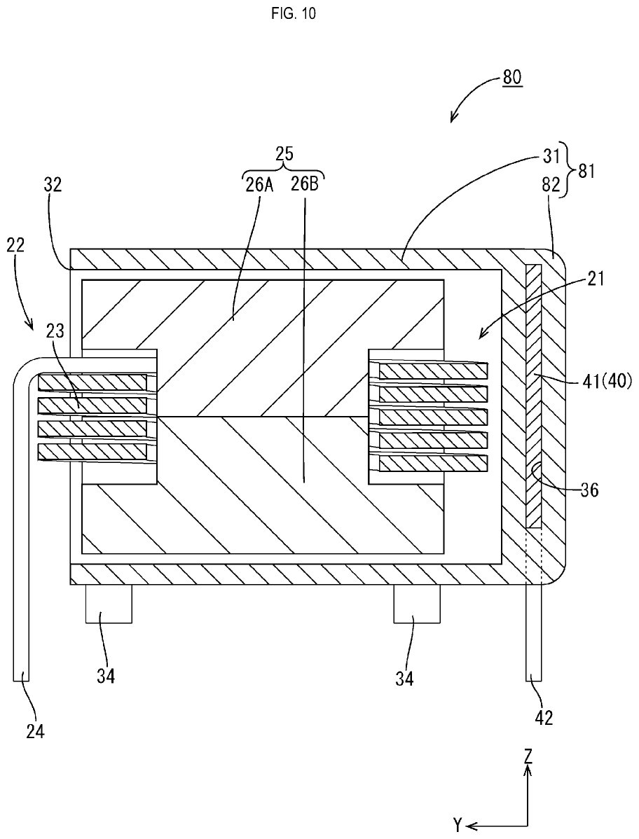

Next, a second embodiment will be described with reference to FIGS. 8 to 10. The bus bar 40 of the coil device 20 of the first embodiment is press-fitted into the case 30, but the bus bar 40 of the coil device 80 in the second embodiment is formed by insertion molding it in a back wall portion 82 of a case 81. Since the other structures are identical to the first embodiment, the configurations similar to the first embodiment are given the same reference numerals, and the description thereof will be omitted.

In the coil device 80, the entire main body portion 41 of the bus bar 40 is embedded in the resin of back wall portion 82 and the entire outer face of the main body portion 41 is in close contact with resin. The connection portions 42 are exposed to the outside of the case 81. The coil device 80 can be formed by arranging the main body portion 41 of the bus bar 40 in a mold (not shown), filling the mold with a synthetic resin, and curing the synthetic resin. According to the second embodiment, since the entire main body portion 41 is embedded in the back wall portion 82, heat conductivity can be improved, and the main body portion 41 can be insulated by the case 81 and prevented from being exposed to the outside.

### Third Embodiment

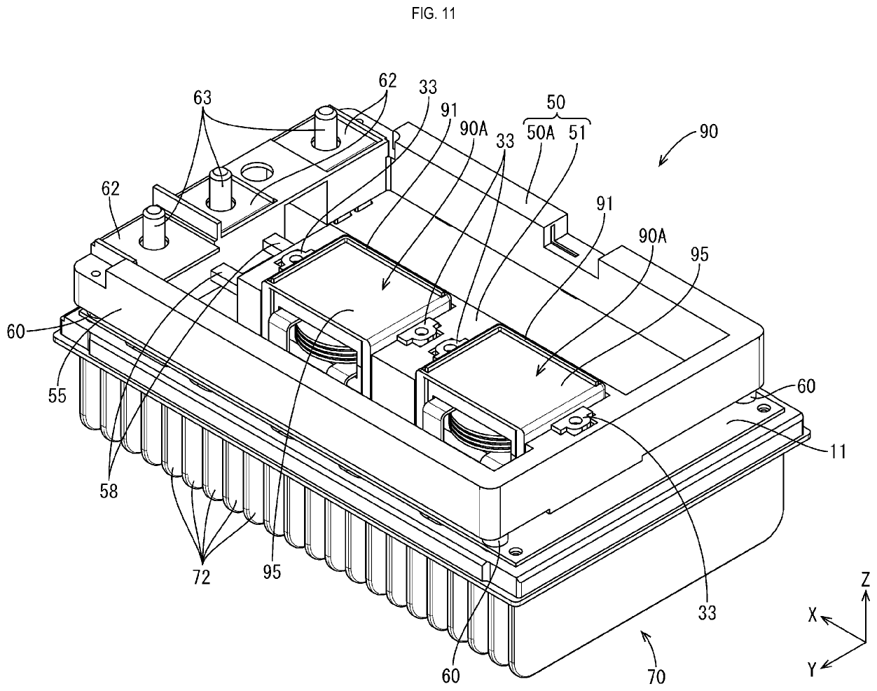

Next, a third embodiment will be described with reference to FIGS. 11 to 16. In a plurality of coil devices 90A of an electrical junction box 90 of the third embodiment, an L-shaped bus bar 91 is held by a case 95. In the following description, the same structures as in the above-described embodiments are denoted with the same reference signs, and the description thereof will be omitted.

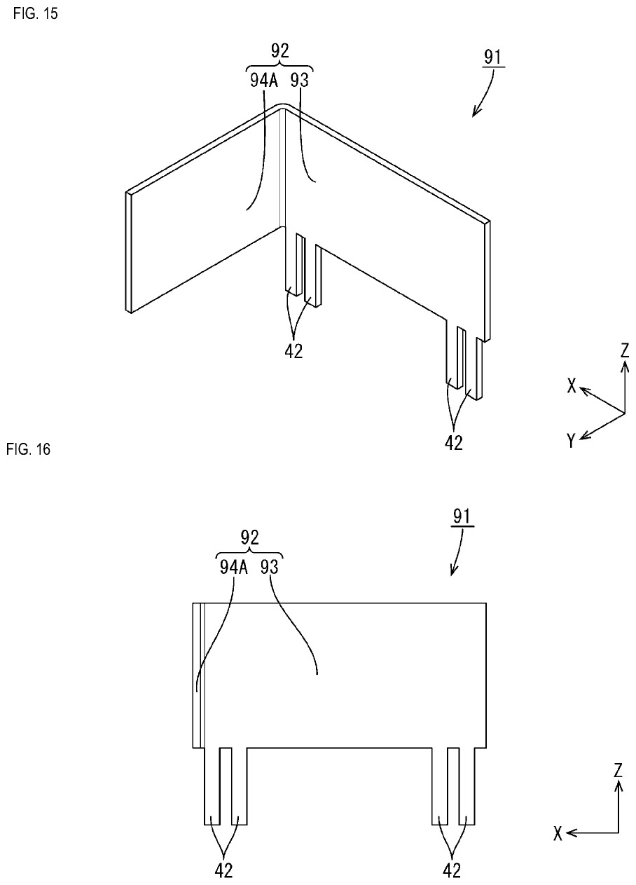

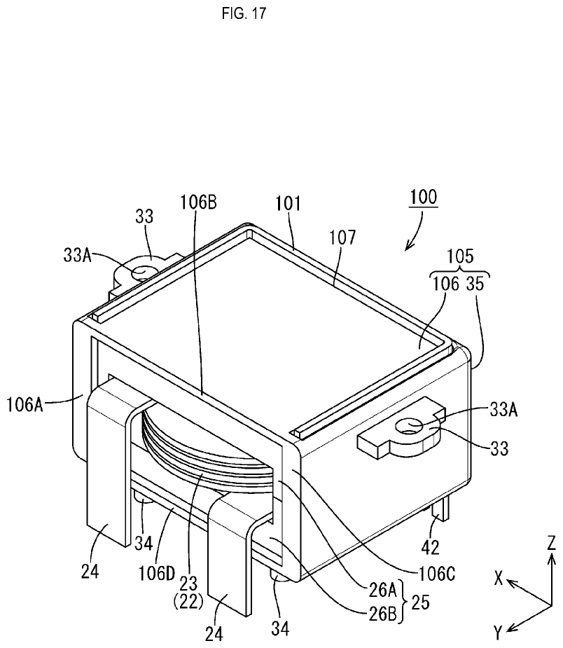

The bus bars 91 of the plurality of coil devices 90A are each formed by punching a plate-shaped metal formed of a material such as copper, a copper alloy, aluminum, or an aluminum alloy, for example. As shown in FIGS. 15 and 16, the bus bar 91 includes a main body portion 92 that has a constant width and extends in an L-shape, and a plurality (in the present embodiment, four) of connection portions 42 that protrude downward from the main body portion 92. The main body portion 92 includes a first plate portion 93 and a second plate portion 94A that extends in the direction perpendicular to (intersecting) the first plate portion 93. The connection portions 42 are formed on the lower end portion of the first plate portion 93 in one piece with the first plate portion 93. The connection portions 42 are each electrically connected to the conductive path on the circuit board 11 by passing through the through hole 12B in the circuit board 11 and being soldered to the through hole 12B.

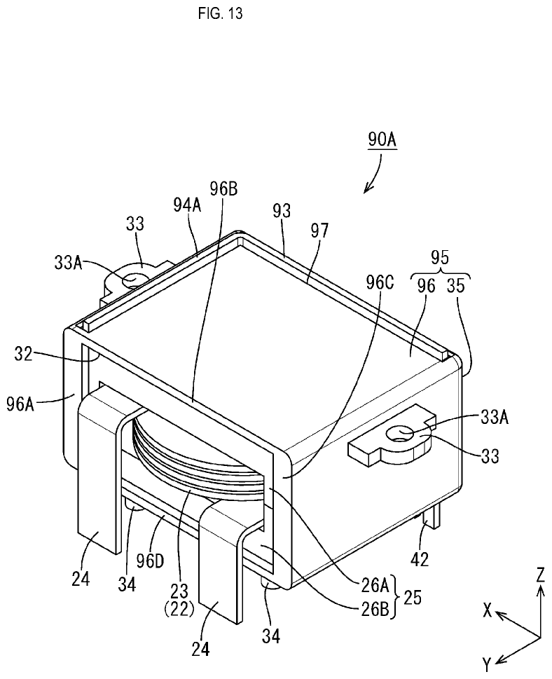

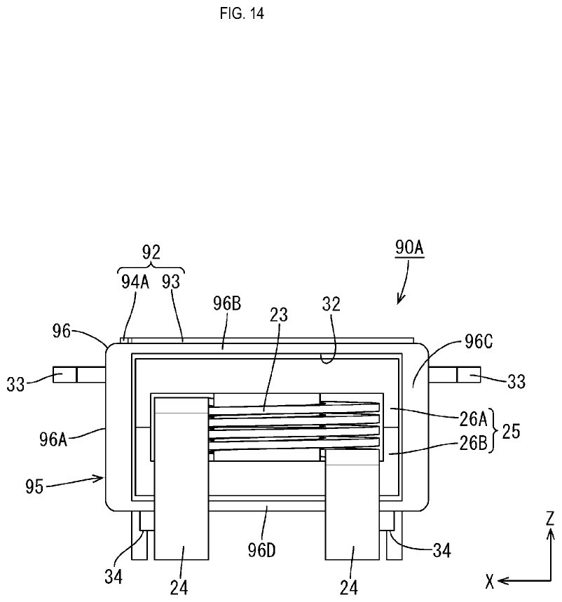

The case 95 is made of an insulative synthetic resin, and for example, an engineering plastic (heat resistance: 100° C. or more, strength: 50 MPa or more, bending elastic modulus: 2.4 GPa or more) can be used. As shown in FIGS. 13 and 14, the case 95 includes a rectangular tubular portion 96 that is shaped in a rectangular tube, and the back wall portion 35 that closes the rectangular tubular portion 96. The rectangular tubular portion 96 includes a pair of opposing wall portions 96A and 96C that flank the coil unit 21 on the left and right, respectively, and a pair of connecting wall portions 96B and 96D that flank the coil unit 21 above and below, respectively. The back wall portion 35 connects and closes the rear end portions of the pair of opposing wall portions 96A, 96C and the pair of the connecting wall portions 96B and 96D. The second plate portion 94A of the bus bar 91 is held in close contact with the opposing wall portion 96A of the pair of opposing wall portions 96A and 96C, and the first plate portion 93 is held in close contact with the back wall portion 35. A rectangular opening portion 32 into which the coil unit 21 can be inserted is formed at the front end portion of the rectangular tubular portion 96.

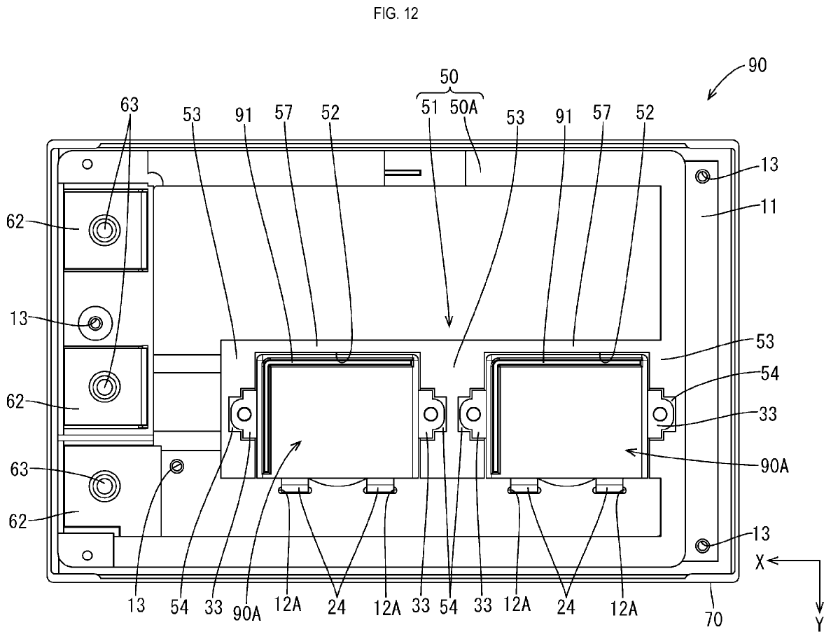

An inlet 97 into which the bus bar 91 can be inserted is formed at the upper end of the opposing wall portion 96A and the back wall portion 35, and the inside of the inlet 97 is a press-fit hole (not shown) into which the bus bar 91 is press-fitted. An outlet 37B from which the connection portion 42 of the bus bar 91 is led out is formed in the lower end portion of the back wall portion 35. The plate face of the main body portion 92 of the bus bar 91 is in close contact with the inner wall of the press-fit hole. As shown in FIGS. 11 and 12, the bus bars 91 of the coil devices 90A are fixed to the case 95 such that the second plate portions 94A are disposed on the left side (on one side in the direction in which the coil devices 90A are arranged), namely, on the terminal portion 62 side. In this manner, electromagnetic noise that emanates from the coil 22 to the terminal portion 62 that is connected to the outside can be shielded by the second plate portion 94A, and thus it is possible to suppress electromagnetic noise from conducting from the coil 22 toward the terminal portion 62. Note, that by covering the electrical junction box 90 with the cover 74 made of metal (see FIG. 3), it is possible for the cover 74 to shield in other directions or electromagnetic noise generated by the other electric components. The coil device 90A is held by the frame 50 in a state where the mounting portion 34 of the case 95 is mounted on the circuit board 11.

According to the third embodiment, the case 95 of the coil device 90A includes the rectangular tubular portion 96 that is shaped like a rectangular tube and that houses the coil unit 21, and the back wall portion 35 that closes the rectangular tubular portion 96, and the rectangular tubular portion 96 includes the pair of opposing wall portions 96A and 96C that oppose each other and the connecting wall portions 96B and 96D that connect the pair of opposing wall portions 96A and 96C to each other, and the bus bar 91 includes the first plate portion 93 that is held in close contact with the back wall portion 35, and the second plate portion 94A that extends in the direction perpendicular to (intersecting) the first plate portion 93 and that is held in close contact with the opposing wall portion 96A.

In this manner, it is possible for the bus bar 91 to shield magnetic flux (electromagnetic noise) that leaks from the coil 22. Furthermore, by providing the second plate portion 94A that comes in close contact with the opposing wall portion 96A, the contact area between the bus bar 91 and the case 95 can be enlarged, and thus heat dissipation of the bus bar 91 can be improved.

### Fourth Embodiment

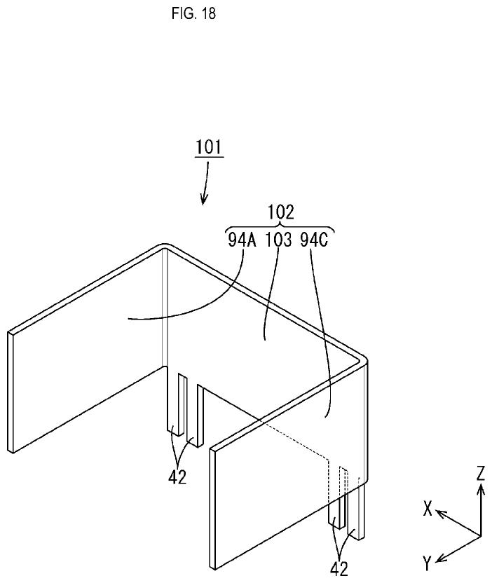

Next, a fourth embodiment will be described with reference to FIGS. 17 and 18. In a coil device 100 of the fourth embodiment, a bus bar 101 is U-shaped. In the following descriptions, the same structures as in the above-described embodiments are denoted with the same reference signs, and the description thereof will be omitted.

As shown in FIG. 18, the bus bar 101 is provided with a main body portion 102 that has a constant width and extends in a U-shape, and a plurality (in the present embodiment, four) of connection portions 42 that protrude downward from the main body portion 102. The main body portion 102 includes a first plate portion 103 that is shaped like a flat plate, and a pair of flat plate-shaped second plate portions 94A and 94C that extend from the left and right end portions of the first plate portion 103 in the direction perpendicular to (intersecting) the first plate portion 103. The connection portions 42 are formed at the lower end portion of the first plate portion 103 in one piece.

As shown in FIG. 17, the case 105 is provided with a rectangular tubular portion 106 that is shaped like a rectangular tube, and a back wall portion 35 that closes the rectangular tubular portion 106. The rectangular tubular portion 96 includes a pair of opposing wall portions 106A and 106C that flank the coil unit 21 on the left and right, respectively, and a pair of connecting wall portions 106B and 106D that flank the coil unit 21 above and below, respectively, and the back wall portion 35 closes the rear end portions of the pair of opposing wall portions 106A and 106C and the pair of the connecting wall portions 106B and 106D. The first plate portion 103 is held in close contact with the back wall portion 35, and the pair of second plate portions 94A and 94C are held in close contact with the pair of opposing wall portions 106A and 106C. An inlet 107 into which the bus bar 101 can be inserted opens in a U-shape at portions of the pair of opposing wall portions 106A and 106C and the back wall portion 35 that correspond to the top end of the case 105, and an press-fit hole (not shown) into which the bus bar 101 is press-fitted is formed inside of the inlet 107. When the bus bar 101 is press-fitted into the press-fit hole, the plate face of the main body portion 102 of the bus bar 101 comes in close contact with the inner wall of the press-fit hole.

According to the fourth embodiment, the pair of first plate portions 103 and second plate portions 94A and 94C are arranged in the surrounding of the coil unit 21, and thus magnetic flux (electromagnetic noise) that leaks from the coil 22 can be shielded by the bus bar 101.

### Fifth Embodiment

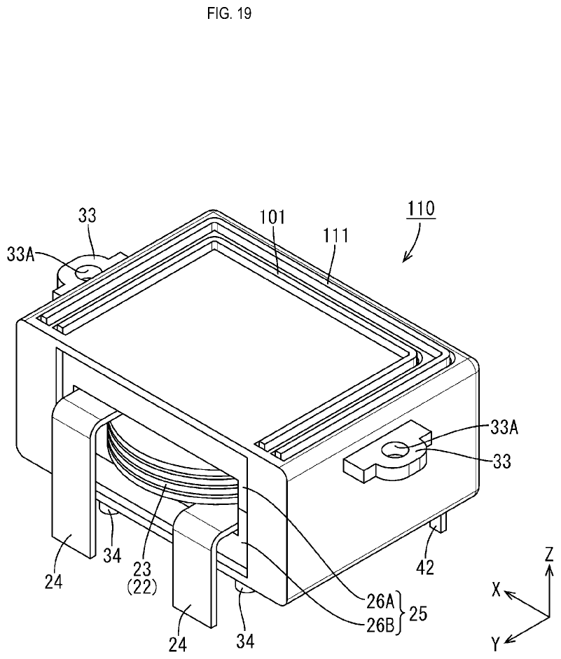

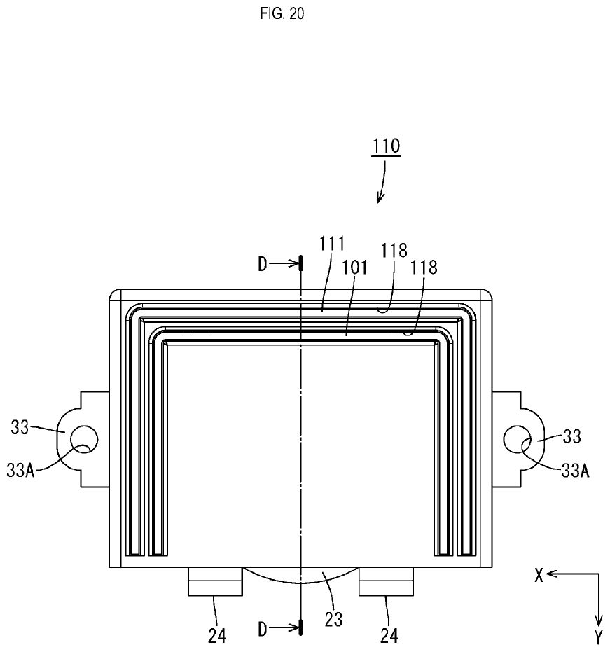

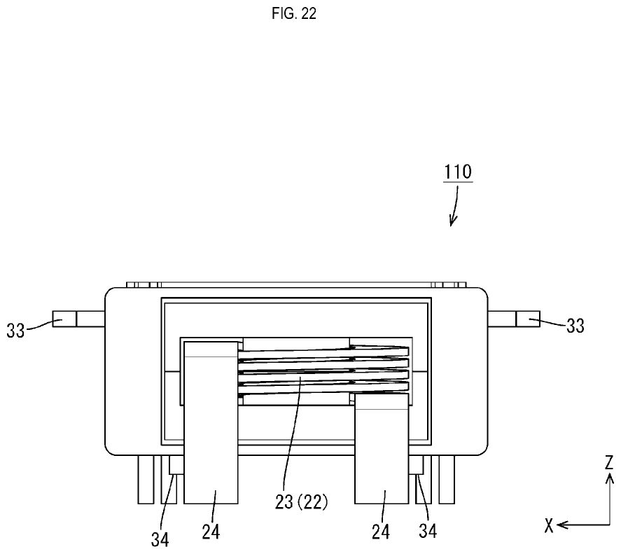

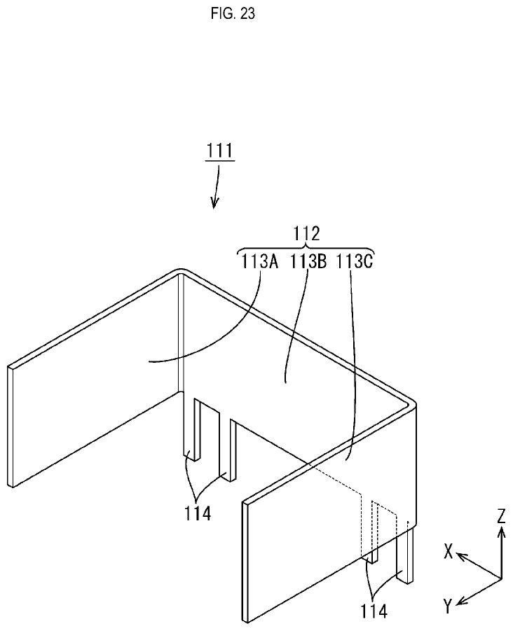

Next, a fifth embodiment will be described with reference to FIGS. 19 to 23. A coil device 110 of the fifth embodiment is formed by two (a plurality of) U-shaped bus bars, namely, a first bus bar 101 and a second bus bar 111 that overlap one another with a gap therebetween. In the following descriptions, the same structures as in the above-described embodiments are denoted with the same reference signs, and the description thereof will be omitted.

The first bus bar 101 is U-shaped, and for example, the same member used in the bus bar 101 of the fourth embodiment can be used. The second bus bar 111 has a size that can surround the outside of the first bus bar 101, and as shown in FIG. 23, is provided with a main body portion 112 that has a constant width and extends in a U-shape, and a plurality (in the present embodiment, four) of connection portions 114 that protrude downward from the main body portion 112. The main body portion 112 includes a first plate portion 113B that is shaped like a flat plate, and a pair of second plate portions 113A and 113C that are shaped in a flat plate and extend from the right and left end portions of the first plate portion 113B frontward (in the direction perpendicular to the first plate portion 113B), respectively. The connection portions 114 are formed at the lower end portion of the first plate portion 113B in one piece, and a space between the pair of connection portions 114 provided at left and right portions of the first plate portion 113B is larger than the space between the pair of connection portions 42. Note, that a current flowing through the bus bar 91 may be, for example, a switching current flowing through a step-up/down portion of the converter. In the present embodiment, it is possible to mutually cancel electromagnetic noise generated by currents flowing in opposite phases by energizing the first bus bar 101 and the second bus bar 111 in opposite phases. Note, that currents flowing through the bus bars 101 and 111 are not limited to be in opposite phases, and may also be in the same phases.

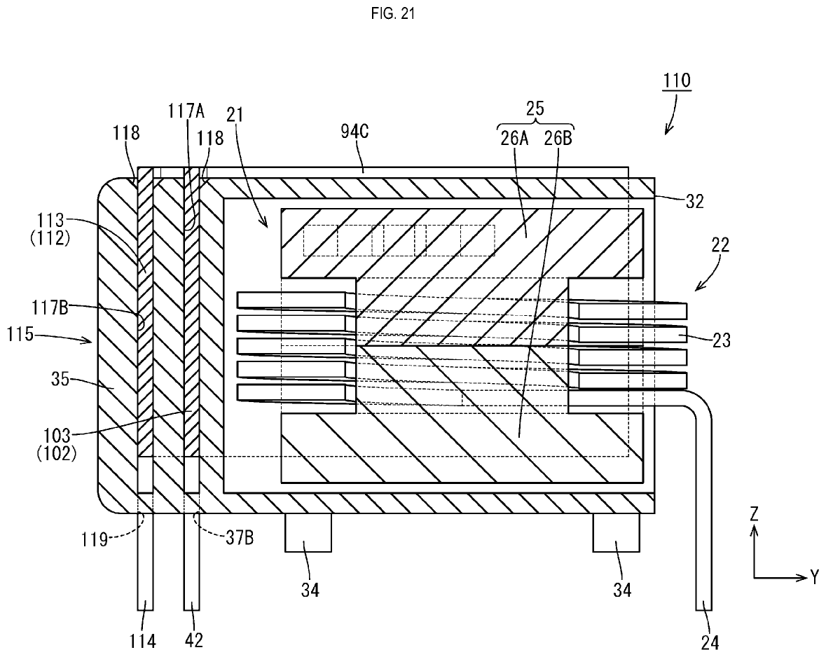

As shown in FIG. 21, a plurality of U-shaped press-fit holes 117A and 117B into which the first bus bar 101 and the second bus bar 111 are press-fitted, respectively, are formed side by side in the pair of opposing wall portions 116A and 116C and the back wall portion 35 of the case 115. The second press-fit hole 117B surrounds the first press-fit hole 117A from the outside of the first press-fit hole 117A. The upper end portions of the two press-fit holes 117A and 117B are a plurality of inlets 118 into which the bus bars 101 and 111 can be inserted. The inlets 118 are cut out in a tapered shape. When the first bus bar 101 and the second bus bar 111 are press-fitted into the press-fit holes 117A and 117B, the plate faces of the first and second bus bars 101 and 111 come in close contact with the inner walls of the press-fit holes 117A and 117B, respectively. Outlets 37B and 119 from which the connection portions 42 and 114 are led out are formed at the lower end portion of the back wall portion 35. The connection portions 42 and 114 are electrically connected to the conductive path of the circuit board 11 by passing through the through hole 12B in the circuit board 11, and being soldered into the through hole 12B (see FIG. 4), and the above-described coil device 110 is held by the frame 50 in a state where the mounting portion 34 of the case 115 is mounted on the circuit board 11.

According to the fifth embodiment, a plurality of bus bars 101 and 111 are provided, and the bus bars 101 and 111 overlap one another with a gap therebetween.

In this manner, magnetic flux (electromagnetic noise) that leaks from the coil 22 can be more reliably shielded by the bus bars 101 and 111.

### OTHER EMBODIMENTS

The technique disclosed in the present specification is not limited to the embodiments illustrated in the above description with reference to the drawings, but for example, the following embodiments are also encompassed in the technical scope of the technique disclosed in the present specification.

Although the above-described embodiments describe that the plate face of the main body portion 41 of the bus bar 40 is placed in the direction perpendicular to the face of the circuit board 11, the present disclosure is not limited to this. The plate face of the main body portion 41 of the bus bar 40 may also be arranged in the direction intersecting the face of the circuit board 11 at an angle other than a right angle.

Although the above-described embodiments describe that the coil device 20 is fixed to the frame 50 and thereafter soldered to the circuit board 11, the present disclosure is not limited to this. It is also possible that the coil device 20 is soldered to the circuit board 11 to form the coil device 45 with circuit board, and thereafter, the coil device 20 is fixed to a frame that has a shape different from the frame 50 by a screw or the like, for example.

Although the above-described embodiments describe that the connection portion 42 is inserted to the through hole 12B, the present disclosure is not limited to this. A configuration is also possible where the connection portion of the bus bar is bent so as to conform to the upper face of the circuit board 11, and the connection portion of the bus bar is soldered to the conductive path at the upper face of the circuit board 11, for example.

Although the bus bars 91, 101, and 111 of the third to fifth embodiments are press-fitted to the cases 95, 105, and 115, respectively, the present disclosure is not limited to this. A configuration is also possible where the bus bars 91, 101, and 111 are held in close contact with the case by the insertion molding. Furthermore, the above-described embodiments describe that the bus bars 40, 91, 101, and 111 are press-fitted to the cases 30, 81, 95, 105, and 115 or held in a close contact therewith by insertion molding, respectively, but the present disclosure is not limited to this. A configuration is also possible where, for example, the case can be closed by a lid, and in a closed state, the lid covers the bus bar 40 in close contact with the bus bar 40.

The number of coil devices is not limited to the number in the above-described embodiments, and may also be one, or three or more. Furthermore, currents flowing in a plurality of phases (e.g., four phases) may also flow through a plurality of bus bars.

1. A coil device comprising:
a coil unit that includes a coil and a magnetic core;
a case that is made of resin and that houses the coil unit, and
a bus bar that includes a connection portion that can be connected to a conductive path of a circuit board, and that is held in close contact with the case, wherein
the case includes a mounting portion that can be mounted on a face of the circuit board.

2. The coil device according to claim 1, wherein
the bus bar includes a plurality of the connection portions, and a main body portion that is shaped like a plate and that connects the connection portions to each other, the two faces of the main body portion being in close contact with the case.

3. The coil device according to claim 1, wherein
the bus bar is shaped like a plate, and the plate face of the bus bar is held by the case in the orientation intersecting the face of the circuit board.

4. The coil device according to claim 1, wherein
the case includes a rectangular tubular portion that is shaped like a rectangular tube and that houses the coil unit, and a back wall portion that closes the rectangular tubular portion,
the rectangular tubular portion includes a pair of opposing wall portions that oppose each other, and a connecting wall portion that connects the pair of opposing wall portions to each other, and
the bus bar includes a first plate portion that is held in close contact with the back wall portion, and a second plate portion that extends in a direction intersecting the first plate portion and that is held in close contact with the opposing wall portions.

5. The coil device according to claim, further comprising:
a plurality of the bus bars, and
the bus bars are arranged so as to overlap one another with a gap therebetween.

6. A coil device with circuit board comprising:
the circuit board on which the mounting portion is mounted, and the coil device according to claim 1, wherein
the circuit board includes a through hole into which the connection portion is inserted and soldered.

7. An electric junction box comprising:
the coil device with circuit board according to claim 6, and
a heat dissipation member that is placed on the circuit board, wherein
the circuit board is a printed circuit board, and the printed circuit board is placed on the heat dissipation member.

8. The electrical junction box according to claim 7, further comprising
a frame that is made of resin and that is mounted on the circuit board, the case being fixed to the frame.
